(19) United States
(12) Patent Application Publication
(10) Pub. No.: US 2004/0189370 A1
(43) Pub. Date: Sep. 30, 2004

(54) On die variable resistor

(76) Inventor: Navashil V. Sharma, Folsom, CA (US)

Correspondence Address: BLAKELY, SOKOLOFF, TAYLOR & ZAFMAN LLP, Seventh Floor, 12400 Wilshire Boulevard, Los Angeles, CA, 90025-1026, US

(21) Appl. No.: 10/397,390

(22) Filed: Mar. 26, 2003

(51) Int. Cl. H03L 5/00

(52) U.S. Cl. 327/308

(57) ABSTRACT

According to one embodiment, an integrated circuit (IC) is disclosed. The IC includes a package, a die mounted within the package, circuit components mounted on the die, and a variable resistance module mounted on the die. The variable resistance module implements series-parallel combinational logic with thermo-encoding to provide variable resistances to the circuit components

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### FIELD OF THE INVENTION

The present invention relates to integrated circuits (ICs); more particularly, the present invention relates to providing a variable resistance on an IC.

### BACKGROUND

There are currently two variable resistance schemes that are implemented at computer system chipsets; the binary scheme and the thermometer scheme. The binary scheme requires relatively few control bits. However, the binary scheme experiences glitching. For instance, when a 1 KΩ-4 KΩ variable resistor of 1% step size, with 128 steps, is targeted, the binary scheme requires 7 bits. Typically, the target resistance is set at half the count of the bits. Thus, in a 7-bit variable resistance design, the target resistance is set at a binary bit value of 64 (1000000).

However, incrementing the binary count from 63 (0111111) to 64 (1000000) may cause the binary weighted resistor to briefly glitch. For instance, 0111111 may change to 0000000 (0), or 1111111 (127), before ultimately settling at 1000000. Thus the maximum error is 99% of the binary weighted resistor's full weighted range.

The thermometer-encoded variable resistor uses a large number of small parallel or series legs. To reduce resistance, more parallel legs are turned on. Typically, only one leg is switched on or off in a given cycle. As a result, the maximum glitch is determined by the chosen leg size. Therefore, the maximum glitch is the same as the step size. However, a small step size requires a very large number of legs and a large number of control signals (e.g., 1% step requires nearly 100 signals) and a large area for the resistor legs and control routing. Consequently, a small step thermometer scheme variable resistor is not feasible.

### BRIEF DESCRIPTION OF THE DRAWINGS

The invention is illustrated by way of example and not limitation in the figures of the accompanying drawings, in which like references indicate similar elements, and in which:

FIG. 1 is a block diagram of one embodiment of a computer system;

FIG. 2 is a block diagram of one embodiment of a variable resistor; and

FIG. 3 illustrates one embodiment of a variable voltage regulator analog block;

FIG. 4 illustrates a logical representation of one embodiment of a variable resistor.

### DETAILED DESCRIPTION

A variable resistor mounted on an integrated circuit is described. In the following detailed description of the present invention numerous specific details are set forth in order to provide a thorough understanding of the present invention. However, it will be apparent to one skilled in the art that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

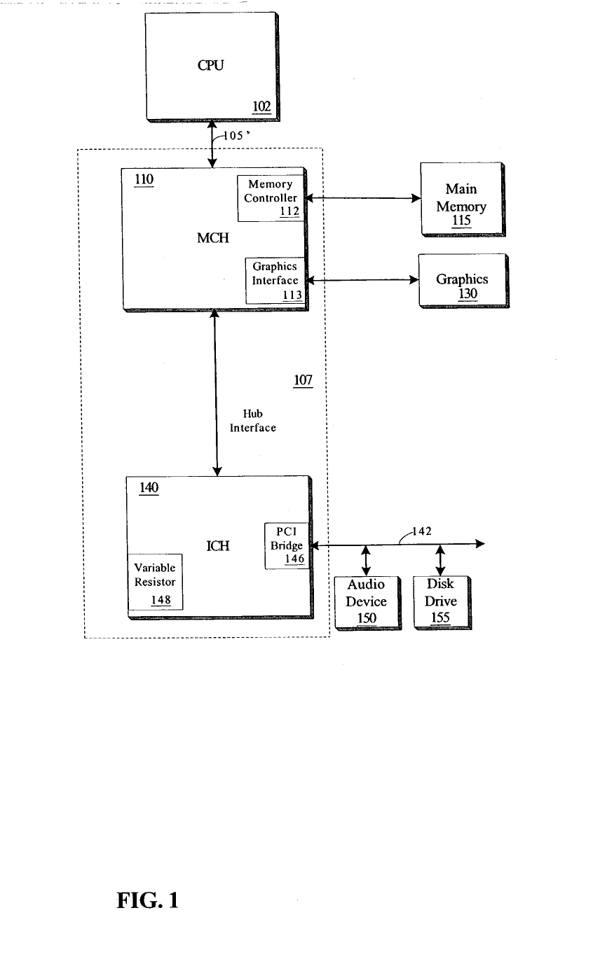

FIG. 1 is a block diagram of one embodiment of a computer system 100. Computer system 100 includes a central processing unit (CPU) 102 coupled to bus 105. In one embodiment, CPU 102 is a processor in the Pentium® family of processors including the Pentium® II processor family, Pentium® III processors, and Pentium® IV processors available from Intel Corporation of Santa Clara; Calif. Alternatively, other CPUs may be used.

A chipset 107 is also coupled to bus 105. Chipset 107 includes a memory control hub (MCH) 110. MCH 110 may include a memory controller 112 that is coupled to a main system memory 115. Main system memory 115 stores data and sequences of instructions that are executed by CPU 102 or any other device included in system 100. In one embodiment, main system memory 115 includes dynamic random access memory (DRAM); however, main system memory 115 may be implemented using other memory types. Additional devices may also be coupled to bus 105, such as multiple CPUs and/or multiple system memories.

MCH 110 may also include a graphics interface 113 coupled to a graphics accelerator 130. In one embodiment, graphics interface 113 is coupled to graphics accelerator 130 via an accelerated graphics port (AGP) that operates according to an AGP Specification Revision 2.0 interface developed by Intel Corporation of Santa Clara, Calif.

In addition, the hub interface couples MCH 110 to an input/output control hub (ICH) 140 via a hub interface. ICH 140 provides an interface to input/output (I/O) devices within computer system 100. ICH 140 may be coupled to a Peripheral Component Interconnect bus adhering to a Specification Revision 2.1 bus developed by the PCI Special Interest Group of Portland, Oreg. Thus, ICH 140 includes a PCI bridge 146 that provides an interface to a PCI bus 142. PCI bridge 146 provides a data path between CPU 102 and peripheral devices.

PCI bus 142 includes an audio device 150 and a disk drive 155. However, one of ordinary skill in the art will appreciate that other devices may be coupled to PCI bus 142. In addition, one of ordinary skill in the art will recognize that CPU 102 and MCH 110 could be combined to form a single chip. Further graphics accelerator 130 may be included within MCH 110 in other embodiments.

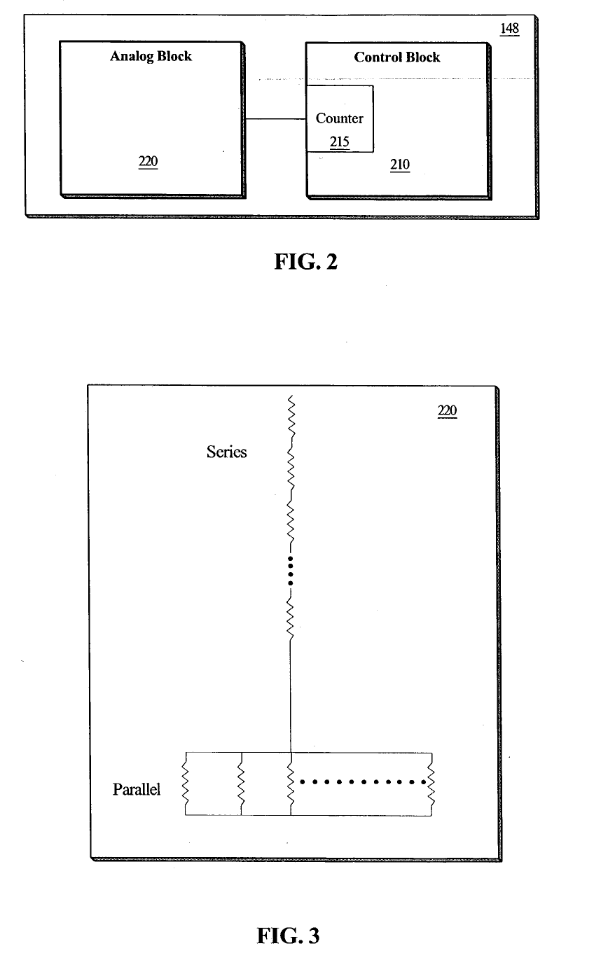

In one embodiment, an on-die variable resistor 148 is integrated on ICH 140. FIG. 2 illustrates one embodiment of variable resistor 148. Variable resistor 148 includes a control block 210 and an analog block 220. Control block 210 includes a counter 215 that transmits control bit patterns to analog block 220. According to one embodiment, the control bits include a parallel portion and a series portion. The series portion controls a group of series resistors within analog block 220 via enabling devices. The parallel portion controls a group of parallel resistors within analog block 220 via enabling devices.

As described above, analog block 220 includes a multitude of resistors that may be varied to adjust resistance. FIG. 3 illustrates one embodiment of analog block 220. Analog block 220 includes a chain of series resistors coupled to a block of parallel resistors. According to one embodiment, there are 16 legs in the series portion and 8 legs in the parallel portion.

In a further embodiment, the center of analog block 220 has a resistance of 2.5 KΩ with a variance of +/−1.6 KΩ. In yet another embodiment, the total resistance of variable resistor 148 is 3.4 KΩ, where each series leg is 8% of the total resistance value (or 200Ω). One of ordinary skill in the art will appreciate that the above values may be varied without departing from the true scope of the invention.

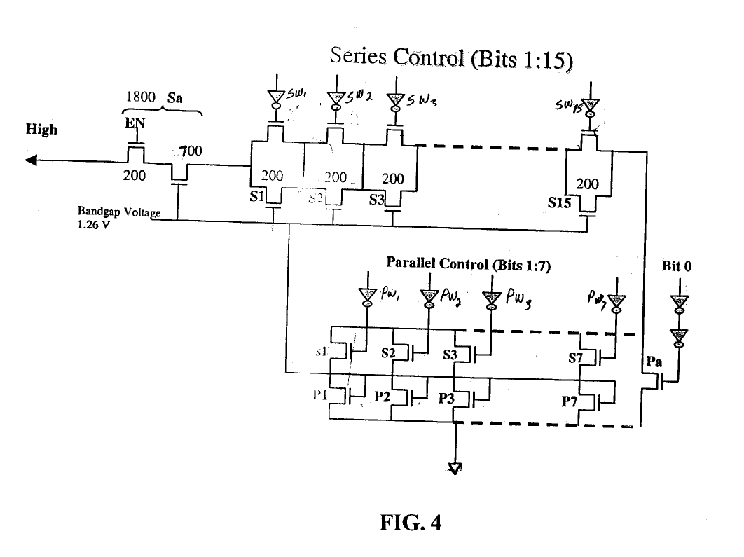

Parallel legs are treated as a thermometer-encoded variable resistor. In one embodiment, when all parallel legs are on the minimum resistance will be 1% of the total resistance value (or 25Ω). When all parallel legs are off, the minimum resistance will be 8% of the total resistance value (or 200Ω). FIG. 4 illustrates a transistor level representation of one embodiment of variable resistor 148.

Referring to FIG. 4, variable resistor 148 includes a series of transistors that implement the resistors described in FIG. 3. According to one embodiment, long channel transistors (Sa, S1-S15, Pa & P1-P7) are coupled to a bandgap reference, and are used as the main resistors. The bandgap voltage reference is used for a constant power supply.

In a further embodiment, short channel transistors (sw1-sw15 & pw1-pw7) are coupled to receive enable bits. Thus, the short channel transistors are used as the enabling devices. One of ordinary skill will appreciate the other types of transistors may be used to implement the resistors and enabling devices. For instance, the main transistors may be implemented with poly or well diffusion transistors.

The enabling device transistors are coupled to each respective resistor transistor. Consequently, each enabling device receives control bits from control block 210. The series resistors receive bits Sa and sw1-sw15, while the parallel resistors receive bits pa and pw1-pw7. As described above, each series is 8% of the total resistance value (or 200Ω).

Also as previously discussed, when all parallel legs are on the minimum resistance will be 1% of the total resistance value (or 25Ω), and when all parallel legs are off, the minimum resistance will be 8% of the total resistance value (or 2500Ω). For example, when all parallel legs are on all transistors are enabled, such that the received enable bits are 00000001. Consequently, the resistance at the parallel portion is 25Ω. Similarly, if all transistors are off, only transistor Pa is enabled such that the received enable bits are 11111111 (e.g., resistance of 200Ω).

TABLE 1

| | | |
|---|---|---|
| Value | Series Legs | Parallel Legs |

| S.P | Series | Bits | Parallel | Bits |
|---|---|---|---|---|
| 0.0 | a | 0000000000000001 | a | 00000001 |
| 0.1 | a | 0000000000000001 | 1 | 00000011 |
| 0.2 | a | 0000000000000001 | 2 | 00000111 |
| 0.3 | a | 0000000000000001 | 3 | 00001111 |
| 0.4 | a | 0000000000000001 | 4 | 00011111 |
| 0.5 | a | 0000000000000001 | 5 | 00111111 |
| 0.6 | a | 0000000000000001 | 6 | 01111111 |
| 0.7 | a | 0000000000000001 | 7 | 11111111 |
| 1.0 | 1 | 0000000000000011 | a | 00000001 |
| 1.1 | 1 | 0000000000000011 | 1 | 00000011 |
| 1.2 | 1 | 0000000000000011 | 2 | 00000111 |
| . | . | . | . | . |
| . | . | . | . | . |
| . | . | . | . | . |
| 15.4 | 15 | 1111111111111111 | 4 | 00011111 |
| 15.5 | 15 | 1111111111111111 | 5 | 00111111 |
| 15.6 | 15 | 1111111111111111 | 6 | 01111111 |
| 15.7 | 15 | 1111111111111111 | 7 | 11111111 |

Table 1 illustrates one embodiment of the variable resistance options associated with variable resistor 148. As shown in Table 1, the resistance is determined by the S and P values. Variable resistor 148 has a minimum resistance of 25Ω plus the resistance of transistor Sa when all transistors are on (e.g., series bits=0000000000000001, parallel bits=00000001), with the exception of transistor Pa.

The series transistors remain off until the change in resistance is to reach a value greater than 200Ω (e.g., series bits=0000000000000001, parallel bits=11111111). The first series leg turns on at 200Ω when the S and P values are 1 and 0, respectively (e.g., series bits=0000000000000011, parallel bits=00000001). The next highest resistance is 250Ω (e.g., series bits=0000000000000001, parallel bits=00000011). These variable resistance steps continue on until the maximum resistance is reached (e.g., series bits=1111111111111111, parallel bits=11111111).

The above-described series-parallel scheme uses series-parallel combinational logic with thermo-encoding to achieve variable resistances. Each resistor has a small transistor used as a bit enable, and a large resistor tied to a bandgap reference. The bandgap voltage reference is used for a constant power supply, resulting in less effect of process, voltage and temperature (PVT) on gate voltage, which improves consistency of linearity of the transistors at PVT, and provides less switching.

Further, the series-parallel scheme reduces glitching associated with binary schemes since in the worst case there is glitch of a parallel leg (e.g., when a parallel leg is being turned off and a serial leg is being turned on). Thus, the largest glitch is 8% as opposed to 99%. The series-parallel variable resistor is also smaller than the binary and thermo-encoded resistors. Thus, less die space is consumed by the series-parallel variable resistor.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as essential to the invention.

1. An integrated circuit (IC) comprising:
a package;
a die mounted within the package;
circuit components mounted on the die; and
a variable resistance module, mounted on the die, to implement series-parallel combinational logic with thermo-encoding to provide variable resistances to the circuit components.

2. The IC of claim 1 wherein the variable voltage resistance module comprises:
an analog block; and
a control block, coupled to the analog block, to transmit control bit patterns to the analog block; and

3. The IC of claim 2 wherein the control block comprises a counter to transmit the control bit patterns.

4. The IC of claim 2 wherein the control bit patterns comprise parallel control bits and series control bits.

5. The IC of claim 4 wherein the analog block comprises:
a plurality of series resistors; and
a plurality of parallel resistors coupled to the series resistors.

6. The IC of claim 5 wherein the plurality of series resistors comprise sixteen resistors and the plurality of parallel resistors comprise eighteen resistors.

7. The IC of claim 5 wherein each of the plurality of series resistors has a 250 ohm resistance and each of the plurality of parallel resistors has a 25 ohm resistance.

8. The IC of claim 5 wherein each the plurality of series resistors and parallel resistors comprise are implemented using long channel transistors.

9. The IC of claim 8 further comprising a short channel transistor coupled to each of the long channel transistors to receive control bits.

10. A computer system comprising:
a central processing unit (CPU); and
a chipset, coupled to the CPU, having a variable resistance module, integrated on the chipset die, to implement series-parallel combinational logic with thermo-encoding to provide variable resistances to the circuit components.

11. The computer system of claim 10 wherein the variable voltage resistance module comprises:
an analog block; and
a control block, coupled to the analog block, to transmit control bit patterns to the analog block.

12. The computer system of claim 11 wherein the control block comprises a counter to transmit the control bit patterns.

13. The computer system of claim 11 wherein the control bit patterns comprise parallel control bits and series control bits.

14. The computer system of claim 13 wherein the analog block comprises:
a plurality of series resistors; and
a plurality of parallel resistors coupled to the series resistors.

15. The computer system of claim 14 wherein the plurality of series resistors comprise sixteen resistors and the plurality of parallel resistors comprise eighteen resistors.

16. The computer system of claim 14 wherein each of the plurality of series resistors has a 250 ohm resistance and each of the plurality of parallel resistors has a 25 ohm resistance.

17. The computer system of claim 14 wherein each the plurality of series resistors and parallel resistors comprise are implemented using long channel transistors.

18. A computer system comprising:
a central processing unit (CPU);
a memory control hub (MCH); and
an input/output control hub (ICH), coupled to the MCH, having a variable resistance module, integrated on the ICH die, to implement series-parallel combinational logic with thermo-encoding to provide variable resistances to the circuit components.

19. The computer system of claim 18 wherein the variable resistance module comprises:
an analog block; and
a control block, coupled to the analog block, to transmit control bit patterns to the analog block.

20. The computer system of claim 19 wherein the control block comprises a counter to transmit the control bit patterns.

21. The computer system of claim 19 wherein the control bit patterns comprise parallel control bits and series control bits.

22. The computer system of claim 21 wherein the analog block comprises:
a plurality of series resistors; and
a plurality of parallel resistors coupled to the series resistors.

23. The computer system of claim 22 wherein the plurality of series resistors comprise sixteen resistors and the plurality of parallel resistors comprise eighteen resistors.

24. The computer system of claim 22 wherein each of the plurality of series resistors has a 250 ohm resistance and each of the plurality of parallel resistors has a 25 ohm resistance.

25. The computer system of claim 22 wherein each the plurality of series resistors and parallel resistors comprise are implemented using long channel transistors.
